(19) United States
(12) Patent Application Publication
(10) Pub. No.: US 2010/0208515 A1
(43) Pub. Date: Aug. 19, 2010

(54) MAGNETIC RANDOM ACCESS MEMORY

(75) Inventors: Masaki Aoki, Kawasaki (JP); Lee Young Min, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/702,847

(22) Filed: Feb. 9, 2010

(30) Foreign Application Priority Data
Feb. 13, 2009 (JP) 2009-030668
Jan. 7, 2010 (JP) 2010-001862

(51) Int. Cl. G11C 11/14; G11C 11/416; H01L 29/82

(52) U.S. Cl. 365/171; 365/189.16; 257/421; 257/E29.323

(57) ABSTRACT

The spin torque transfer magnetic random access memory includes a magnetic tunnel junction element including a pinned layer, a free layer, and a tunnel insulating film formed between the pinned layer and the free layer, and a memory cell select transistor having one diffused region electrically connected to a side of the fee layer of the magnetic tunnel junction element.

### CROSS REFERENCE TO RELATED APPLICATIONS

This application is based upon and claims the benefit of priority of the prior Japanese Patent Application No. 2009-030668, filed on Feb. 13, 2009, and the Japanese Patent Application No. 2010-001862, filed on Jan. 7, 2010, the entire contents of which are incorporated herein by reference.

### FIELD

The embodiments discussed herein are related to an MRAM (Magnetic Random Access Memory), more specifically, a spin torque transfer MRAM.

### BACKGROUND

As a nonvolatile memory device, MRAM using a magnetoresistive effect element is noted. As the magnetoresistive effect element, an MTJ (Magnetic Tunnel Junction) element, for example, is used. In such MRAM, the write of information is made with magnetic fields generated by current flowing in the write lines.

Recently, as the MRAM with no write lines, a spin torque transfer MRAM is developed. In the spin torque transfer MRAM, the bidirectional write, which writes by changing directions of current flowing in the MTJ element, is used.

The following are examples of related: Japanese Laid-open Patent Publication No. 2005-503669, and Japanese Laid-open Patent Publication No. 2008-198317.

However, the conventional spin torque transfer MRAM has to use a memory cell transistor of whose gate width is large so as to obtain current necessary to write, which increases the cell area, resultantly often lowering the integration.

### SUMMARY

According to one aspect of an embodiment, there is provided a magnetic random access memory including a magnetic tunnel junction element including a pinned layer, a free layer, and a tunnel insulating film formed between the pinned layer and the free layer, and a memory cell select transistor having one diffused region electrically connected to a side of the free layer of the magnetic tunnel junction element.

According to another aspect of an embodiment, there is provided a magnetic random access memory including a magnetic tunnel junction element including a pinned layer, a free layer, and a tunnel insulating film formed between the pinned layer and the free layer, a memory cell select transistor having one diffused region electrically connected to a side of the free layer of the magnetic tunnel junction element, a bit line electrically connected to a side of the pinned layer of the magnetic tunnel junction element, a source line extended in parallel with the bit line and electrically connected to the other diffused region of the memory cell select transistor, and a word line extended, intersecting the bit line and electrically connected to a gate electrode of the memory cell select transistor.

The object and advantages of the embodiment will be realized and attained by means of the elements and combinations particularly pointed out in the claims.

It is to be understood that both the foregoing general description and the following detailed description are exemplary and explanatory and are not restrictive of the embodiments, as claimed.

### BRIEF DESCRIPTION OF DRAWINGS

FIG. 1 is a diagrammatic plan view of the spin torque transfer MRAM according to a first embodiment;

FIGS. 2A-2C are diagrammatic sectional views of respective parts of the spin torque transfer MRAM according to the first embodiment;

FIG. 3 is a diagrammatic sectional view of the MTJ element forming the spin torque transfer MRAM according to the first embodiment;

FIG. 4 is a view of the equivalent circuit of the memory cell forming the spin torque transfer MRAM according to the first embodiment;

FIG. 5 is a diagrammatic perspective view of the memory cell forming the spin torque transfer MRAM according to the first embodiment;

FIGS. 6A and 6B are views explaining the write operation of the spin torque transfer MRAM according to the first embodiment;

FIG. 7 is a graph explaining the current driving power and the write current of the memory cell select transistor;

FIG. 8 is a diagrammatic plan view of the spin torque transfer MRAM according to a second embodiment;

FIGS. 9A-9C are diagrammatic sectional views of respective parts of the spin torque transfer MRAM according to the second embodiment;

FIG. 10 is a diagrammatic sectional view of the MTJ element forming the spin torque transfer MRAM according to a third embodiment;

FIG. 11 is a diagrammatic sectional view of the MTJ element forming the spin torque transfer MRAM according to a fourth embodiment;

FIG. 12 is a diagrammatic plan view of the spin torque transfer MRAM according to a reference embodiment;

FIGS. 13A and 13B are diagrammatic sectional views of respective parts of the spin torque transfer MRAM according to the reference embodiment;

FIG. 14 is a diagrammatic sectional view of the MTJ element of the bottom pin type of the spin torque transfer MRAM according to the reference embodiment;

FIG. 15 is a conceptual perspective view of the 1T-1MTJ memory cell forming the spin torque transfer MRAM according to the reference embodiment;

FIGS. 16A and 16B are views explaining the write operation of the spin torque transfer MRAM according to the reference embodiment;

FIGS. 17A and 17B are views explaining the characteristics of the MTJ element;

FIG. 18 is a view explaining the write current of the spin torque transfer MRAM according to the reference embodiment; and

FIG. 19 is a view explaining the simulation result.

### DESCRIPTION OF EMBODIMENTS

### Reference Embodiment

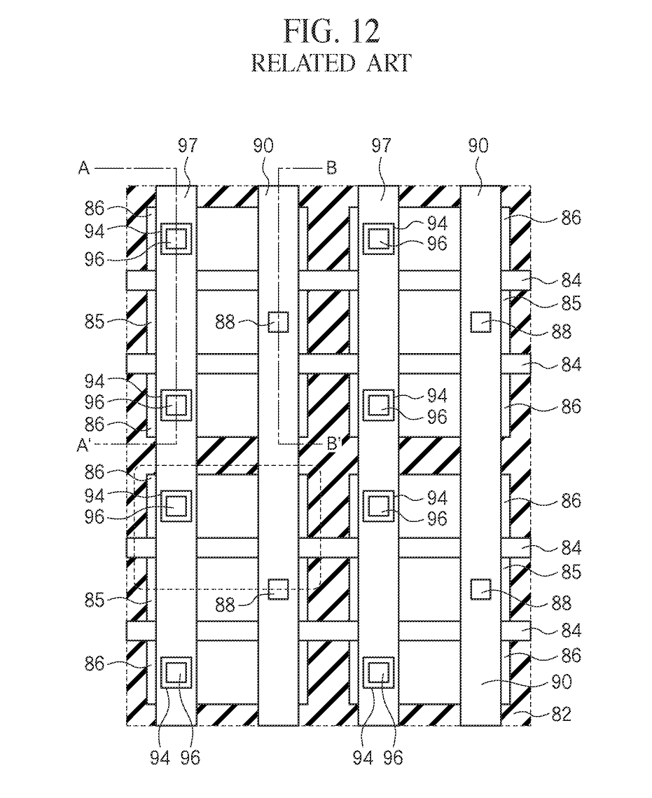

The spin torque transfer MRAM according to a reference embodiment will be explained with reference to FIGS. 12 to 19.

First, the structure of the spin torque transfer MRAM according to the present embodiment will explained with reference to FIGS. 12 to 14.

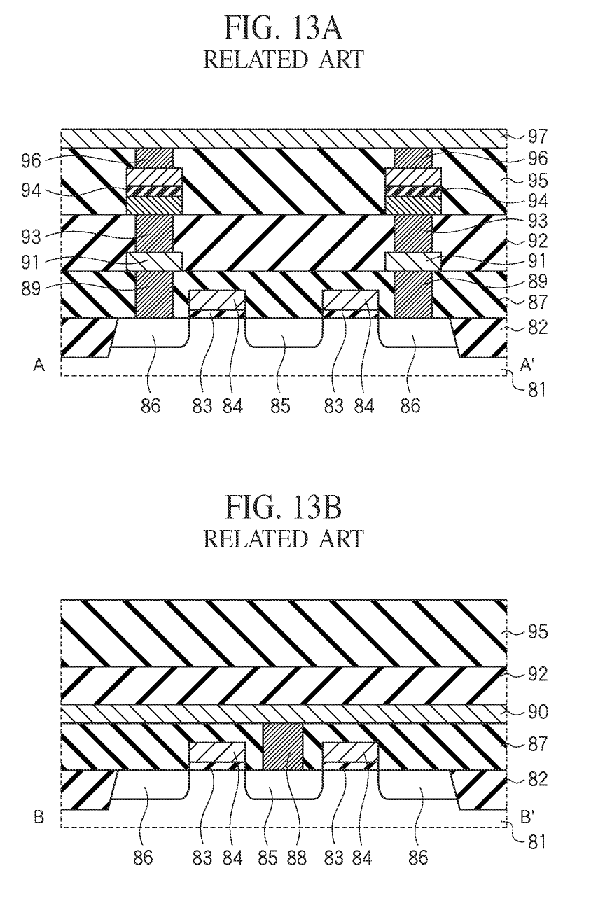

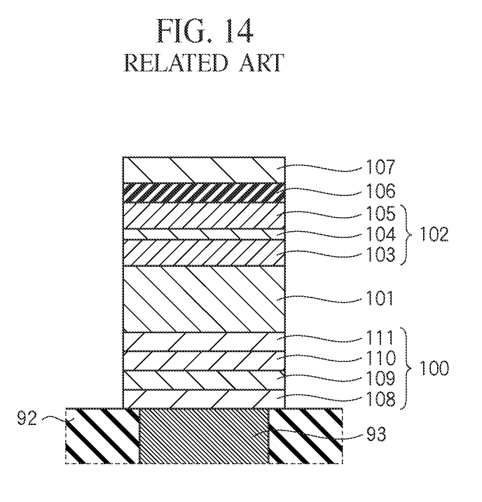

FIG. 12 is a diagrammatic plan view of the spin torque transfer MRAM according to the present embodiment. FIGS. 13A and 13B are diagrammatic sectional views of the spin torque transfer MRAM according to the present embodiment. FIG. 13A is the diagrammatic sectional view along the one-dot chain line interconnecting A-A′ in FIG. 12. FIG. 13B is the diagrammatic sectional view along the one-dot chain line interconnecting B-B′ in FIG. 12. FIG. 14 is a diagrammatic sectional view of a bottom pin type MTJ element of the spin torque transfer MRAM according to the present embodiment. To simplify the explanation, the detailed structures, etc. of the extension regions, the sidewall spacers, and the inter-level insulating films are neither illustrated nor explained.

As illustrated in FIGS. 12, 13A and 13B, a device isolation region 82 for defining device forming regions is formed in a p-type silicon substrate 81. Over the surface of each device region, gate electrodes to be word lines 84 are formed with a gate insulating film 83 interposed therebetween. In the device forming region on both sides of the gate electrodes, an n-type source region 85 and an n-type drain region 86 are formed. Thus, in the device forming regions, memory cell select transistors each including the gate electrode formed of the word line 84 and the n-type source region 85 and the n-type drain region 86 are formed. In each device forming region, two memory cell select transistors including the n-type source region 85 in common are formed.

Over the p-type silicon substrate 81 with the memory cell select transistors formed on, an inter-level insulating film 87 is formed. In the inter-level insulating film 87, plugs 88 connected to the n-type source regions 85, and plugs 89 connected to the n-type drain regions 86 are buried. Over the inter-level insulation film 87 with the plugs 88, 89 buried in, source lines 90 electrically connected to the n-type source regions 85 via the plugs 88 and extended, crossing the word line 84, and interconnection conductive layers 91 electrically connected to the n-type drain regions 86 via the plugs 89 are formed.

Over the inter-level insulating film 87 with the source lines 90 and the interconnection conductive layers 91 formed on, an inter-level insulating film 92 is formed. In the inter-level insulating film 92, plugs 93 connected to the interconnection conductive layers 91 are buried. Over the inter-level insulating film 91 with the plugs 93 buried in, bottom pin type MTJ elements 94 connected to the plugs 93 are formed.

Over the inter-level insulating film 92 with the MTJ elements 94 formed on, an inter-level insulating film is formed. In the inter-level insulating film 95, plugs 86 connected to the MTJ elements 94 are buried. Over the inter-level insulating film 95 with the plugs 96 buried in, bit lines 97 connected to the plugs 96 are formed.

The MTJ elements 94 are not specifically limited as long as the MTJ elements 94 are bottom pin type MTJ element, but, for example, the MTJ element of the structure illustrated in FIG. 14 may be used.

The MTJ element 94 illustrated in FIG. 14 includes an, e.g., 15 nm-thickness PtMn antiferromagnetic layer 101, a coupled pinned layer 102 of a CoFeB layer 103 (of, e.g., a 2.3 nm-thickness)/a Ru layer 109 (of, e.g., a 0.68 nm-thickness)/a CoFeB layer 105 (of, e.g., a 2.2 nm-thickness), an, e.g., 1.16 nm-thickness MgO tunnel insulating film 106, and an, e.g., 2 nm-thickness CoFeB free layer 107 sequentially stacked over the lower electrode 100 connected to the plug 93 of W. The upper electrode 100 is not specifically limited but may be formed of, e.g., the layer structure of a Ta film 108/a Ru film 109/a NiFe film 110/a Ta film 111. The upper electrode has the usual constitution and is not explained here.

The bottom pin type MTJ element is used here, because the planarity of the antiferromagnetic layer influences on the characteristics thereof, and in terms of the fabrication process, the lower location of the pinned layer facilitates the processing. The bottom pin structure is characterized by more facilitating the processing with dry etching than the top pin structure and making better the pinning (pin characteristics) of the magnetic field of the pinned layer.

As illustrated in FIG. 12, the source lines 90 and the bit lines 97 are arranged in parallel with each other, and the word lines are arranged, crossing the source lines 90 and the bit lines 97. The respective memory cell is formed of one transistor and one MTJ element.

Then, the method of manufacturing the spin torque transfer MRAM according to the present embodiment will be explained with reference to FIGS. 13A and 13B.

As illustrated in FIGS. 13A and 13B, the device isolation region 82 is formed in the p-type silicon substrate 81, and the gate electrodes to be the word lines 84 are formed over the surface of the device forming regions surrounded by the device isolation regions 82 with the gate insulating film 83 interposed therebetween. On both sides of each gate electrode, an n-type source region 85 and an n-type drain region 86 are formed. The source region and the drain region are relatively called, and in this case, for the convenience of the explanation, the region connected to the bit line is the drain region.

Then, the inter-level insulating film 87 is formed, and then the plugs 88 connected to the n-type source regions 85, and the plugs 89 connected to the drain regions 86 are formed. The source lines 90 connected to the plugs 88 are formed. The interconnection conductive layers 91 connected to the plugs 89 are formed.

Then, the inter-level insulating film 87 is formed. Then, the plugs 93 connected to the interconnection conductive layers 91 are formed, and the MTJ elements 94 are formed, connected to the plugs 93. Next, the inter-level insulating film 95 is formed, and then the plugs 96 connected to the MTJ elements 94 are formed. The bit lines 97 connected to the plugs 96 are formed. Thus, the basic structure of the spin torque transfer MRAM according to the present embodiment is completed.

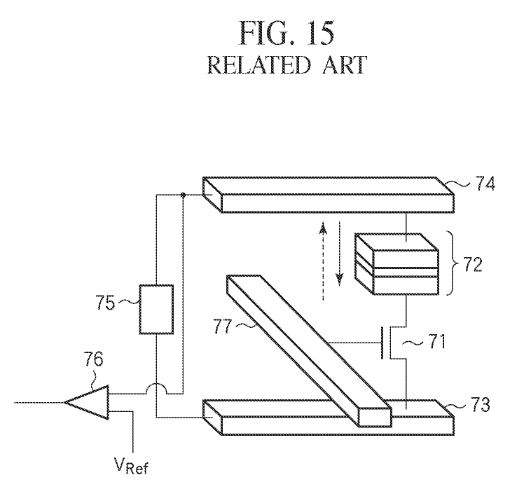

Next, the operation of the spin torque transfer MRAM according to the present embodiment will be explained with reference to FIGS. 15 to 19.

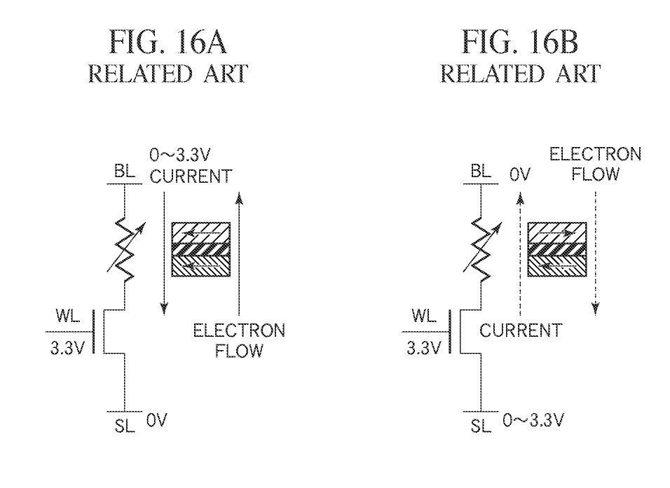

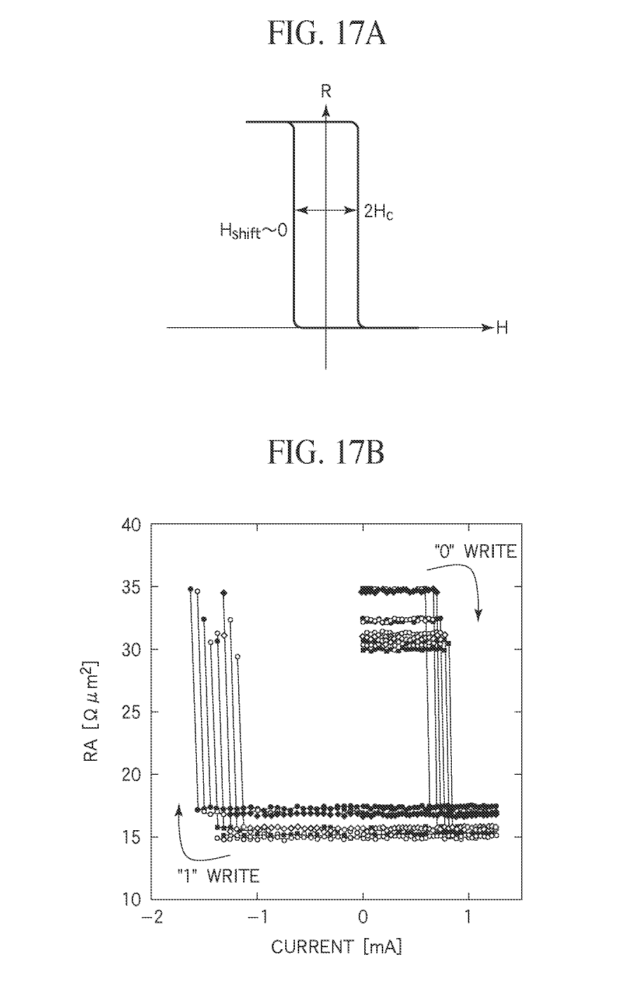

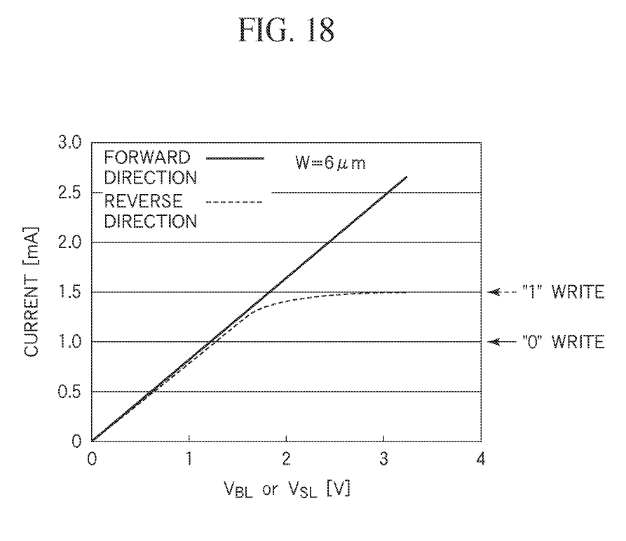

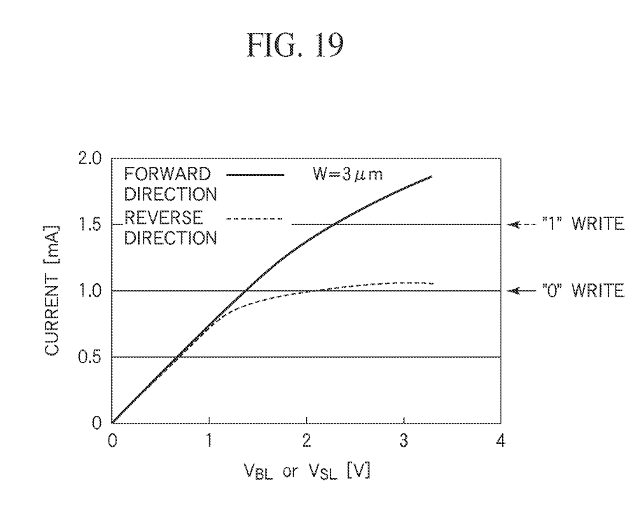

FIG. 15 is a conceptual perspective view of the 1T-1MTJ memory cell forming the spin torque transfer MRAM according to the present embodiment. FIGS. 16A and 16B are views explaining the write operation of the spin torque transfer MRAM according to the present embodiment. FIGS. 17A and 17B are views explaining the characteristics of the MTJ element. FIG. 18 is a view explaining the write current of the spin torque transfer MRAM according to the reference embodiment. FIG. 19 is a view explaining the simulation result.

The memory cell includes a memory cell select transistor 1 and an MTJ element 2. A bidirectional write/read voltage generator 75 is connected between the source line 73 and the bit line 74. The bit line 74 is connected also to a sense amplifier 76. The read output from the bit line 74 is outputted to the sense amplifier 76, and information can be read. In this case, as described above, the MTJ element 72 of the bottom pin type having the pinned layer on the side of the lower electrode is used, because, in terms of the fabrication process, the location of the antiferromagnetic layer, i.e., the pinned layer facilitates the formation of the MTJ element. In the drawing, Reference number 77 indicates the word line.

FIGS. 16A and 16B are views explaining the write operation of the spin torque transfer MRAM. FIG. 16A is a view explaining the write operation of the low resistance state “0”, in which the directions of the spins (magnetization directions) of the free layer and the pinned layer are parallel with each other. FIG. 16B is a view explaining the write operation of the high resistance state “1”, in which the directions of the spins (magnetization directions) of the free layer and the pinned layer are antiparallel with each other.

As shown in FIG. 16A, when “0” is written, the source line is grounded, and a write voltage V_{BL} is applied to the bit line to flow forward current in the MTJ element. In this case, opposite to the current, electrons flow from the pinned layer to the free layer, in the pinned layer, electrons of the same spin direction as a magnetization direction of the pinned layer are selectively passed to the free layer, and a magnetization direction of the free layer is brought into parallel with the magnetization direction of the pinned layer.

On the other hand, as shown in FIG. 16B, when “1” is written, the bit line is grounded, and a write voltage V_{SL} is applied to the source line to flow reverse current in the MTJ element. In this case, opposite to the current, electrons flow from the free layer to the pinned layer, in the pinned layer, electrons of a spin direction opposite to the a magnetization direction of the pinned layer are reflected back to the free layer, and a magnetization direction of the free layer is made antiparallel with the magnetization direction of the pinned layer.

In such write operation, the circuit operation is asymmetric, and, depending on the write directions, the current driving power differs about 2 times. That is, when the memory cell select transistor and the MTJ element to be the resistor are connected, current flows with the side (the drain region) the resistor connected to having a higher potential, i.e., the current is forward, the other side of the memory cell select transistor (the source region) is grounded, and the so-called common source circuit operation is made.

On the other hand, oppositely, when the other side of the memory cell select transistor (the source region) has a high potential to flow current, because of the resistor is connected to the other side of the memory cell select transistor (the drain region), the so-called source follower circuit operation is made, and the current driving power is small.

On the other hand, the write characteristics of the MTJ element are also asymmetric. This will be explained with reference to FIGS. 17A and 17B.

FIG. 17A is a view explaining the R (resistance)-H (magnetic field) characteristics of the MTJ element, and the R-H characteristics themselves are substantially symmetric, and the H shift is substantially 0.

FIG. 17B is a view explaining the spin torque transfer characteristics of the MTJ element. When “0” is written with the forward current, as the write voltage V_{SL} is increased to increase the current, the spin-flip takes place at about 1 mA, and the low resistance state is made.

On the other hand, when “1” is written with the reverse current, as the write voltage V_{SL} is increased to increase the absolute value of the current the spin-flip takes place at about −1.5 mA, and the high resistance state is made. For the “1” write, the spin torque transfer current (write current) is larger. This is predicted based on the theoretical formula (Slonczewski formula) and is a characteristic generally confirmed experimentally. The characteristics of 14 samples are shown here and have a little scatter.

Thus, even when the R-H characteristics are substantially symmetric, and the H shift is substantially 0, the “1” write, i.e., the antiparallel write has larger write current than the parallel write. In the present embodiment, in order to ensure the drive current for the “1” write, a MOSFET of, e.g., 6 μm gate width W is used as the memory cell select transistor.

FIG. 18 is a view explaining the write current of the spin torque transfer MRAM according to the present embodiment. The gate width W of the memory cell select transistor is 6 μm so that the reverse current can have about 1.5 mA for the “1” write. The gate width is too sufficiently enough for the forward current for the “0” write.

However, as described above, the characteristics of the single body of the MTJ element is that the write current becomes large when the write is made by flowing current from the pinned layer to the free layer. On the other hand, the 1T-1MTJ memory cell has the source follower circuit drive in which when current flows from the pinned layer to the free layer, the current driving power of the memory cell select transistor is low.

Then, the operation of the memory cell select transistor in the write operation was analyzed. In the circuit simulation, the memory cell select transistor was a MOSFET of a 3 μm-gate width W and a 0.34 μm-gate length L, the drive voltage was 3.3 V, and the resistance of the MTJ element was 1 kΩ.

FIG. 19 is a view explaining the simulation result. As shown in FIG. 19, in the write from the side of the source line (the reverse current), the current does not easily flow. This is because the resistance of the MTJ element is connected to the source side of the memory cell select transistor, and when the current flows, the potential of the source rises, and the gate-source voltage lowers.

The analysis of the operation of the memory cell of the 1T-1MTJ has found that the current which can be flown changes depending on the write directions, and the worst case is the write from the side of the source line, and the write from the side of the bit line has the allowable current value which is about twice that of the write from the side of the source line. Accordingly, the memory cell select transistor of, e.g., a 3 μm-gate width W cannot make stable “1” write.

Then, in the present embodiment, the memory cell select transistor of 6 μm gate width W, which is large, is used. Thus, even in the write from the side of the source line (the reverse current), current of about 1.5 mA can be obtained by the application of a voltage of 3.3 V.

However, the use of the large memory cell select transistor whose gate width W is, e.g., 6 μm makes the cell area large, and lowers the integration. Preferably, the memory cell transistor of a smaller size is used to thereby make the write efficient.

### A First Embodiment

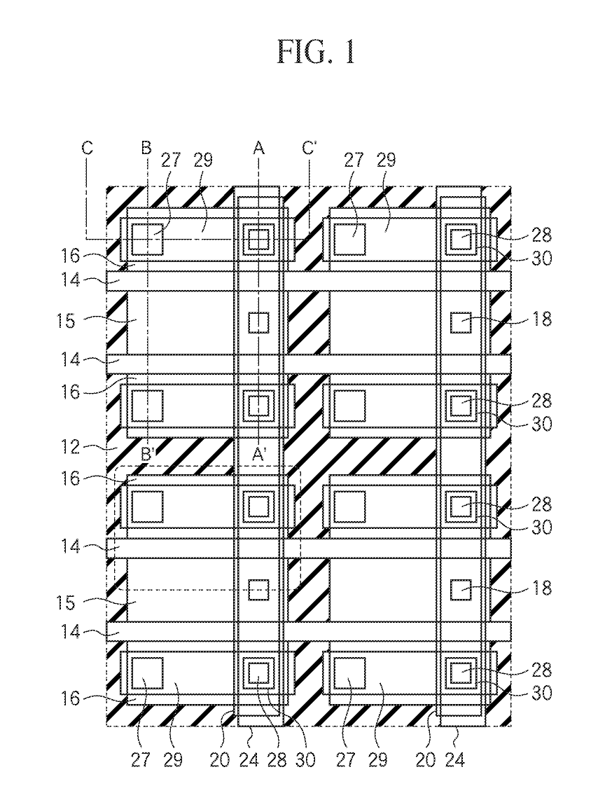

The spin torque transfer MRAM according to a first embodiment will be explained with reference to FIGS. 1 to 7.

First, the structure of the spin torque transfer MRAM according to the present embodiment will be explained with reference to FIGS. 1 to 4.

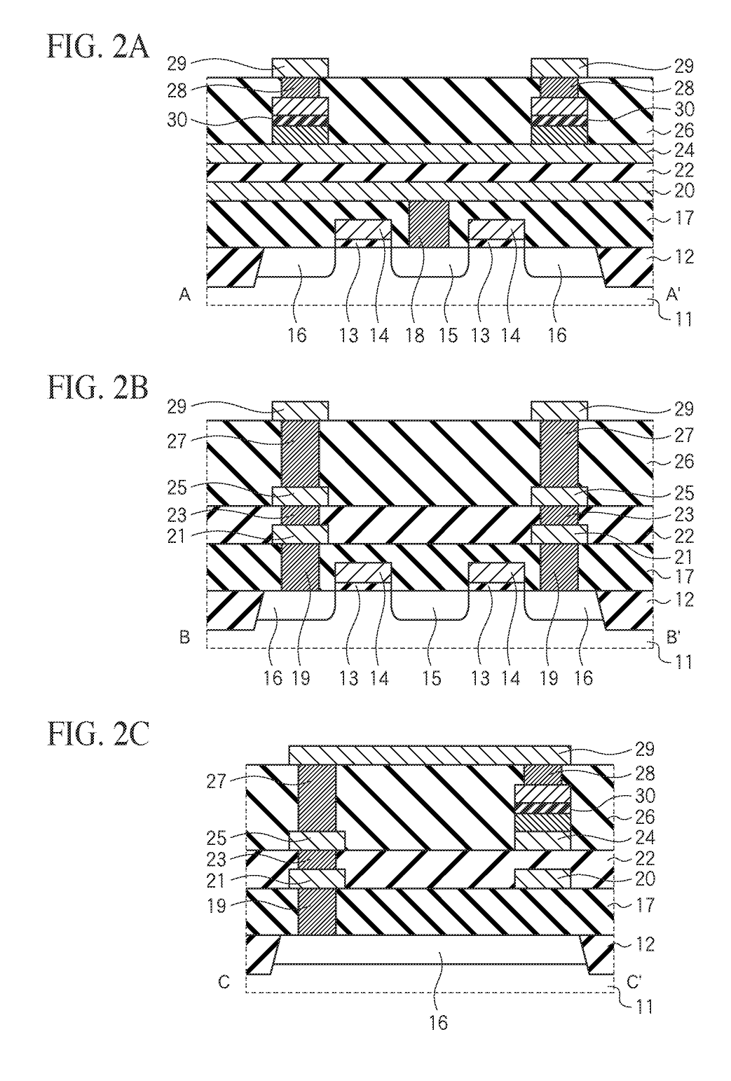

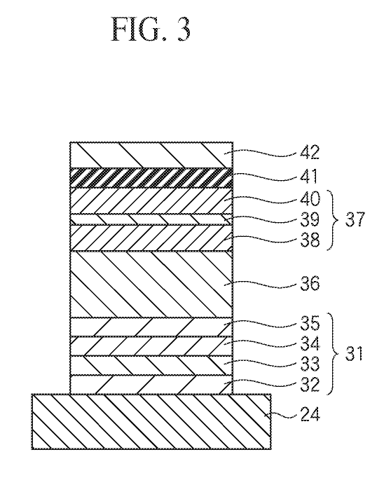

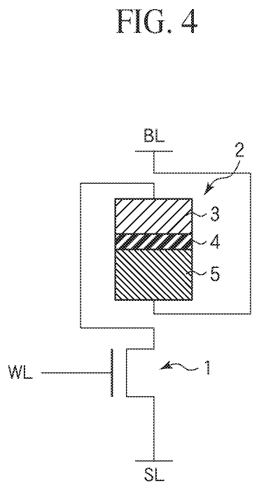

FIG. 1 is a diagrammatic plan view of the spin torque transfer MRAM according to the present embodiment. FIGS. 2A-2C are diagrammatic sectional views of the respective parts of the spin torque transfer MRAM according to the present embodiment. FIG. 2A is the diagrammatic sectional view along the one-dot chain line interconnecting A-A′ in FIG. 1. FIG. 2B is the diagrammatic sectional view along the one-dot chain line interconnecting B-B′ in FIG. 1. FIG. 2C is the diagrammatic sectional view along the one-dot chain line interconnecting C-C′ in FIG. 1. FIG. 3 is a diagrammatic sectional view of the MTJ element included in the spin torque transfer MRAM according to the present embodiment. FIG. 4 is a view illustrating the equivalent circuit of the memory cell forming the spin torque transfer MRAM according to the present embodiment. To simplify the explanation, the drawings and the explanation of the detailed structures of the extension regions, the sidewall spacers and the inter-level insulating films are omitted.

As illustrated in FIGS. 1, 2A and 2B, device isolation regions 12 for defining device forming regions are formed in a p-type silicon substrate 11. Over the surface of each device forming region, gate electrodes to be word lines 14 are formed with a gate insulating film 13 interposed therebetween. In the device forming regions on both sides of the gate electrodes, an n-type source regions 15 and n-type drain regions 16 are formed. Thus, in the device forming region, memory cell select transistors each including the gate electrode formed by the word line 14, the n-type source region 15 and an n-type drain region 16 are formed. In each device region, two memory cell select transistors including the n-type source region 15 in common are formed.

Over the p-type silicon substrate 11 with the memory cell select transistors formed on, an inter-level insulating film 17 is formed. In the inter-level insulating film 17, a plug 18 connected to the n-type source regions 15, and plugs 19 connected to the n-type drain regions 16 are buried. Over the inter-level insulating film 17 with the plugs 18, 19 buried in, source lines 20 electrically connected to the n-type source regions 15 via the plugs 18 and extended, intersecting the word lines 17, and interconnection conductive layers 21 electrically connected to the n-type drain regions 16 via the plugs 18 are formed.

Over the inter-level insulating film 17 with the source lines 20 and the interconnection conductive layers 21 formed on, an inter-level insulating film 22 is formed. In the inter-level insulating film 22, plugs 23 connected to the interconnection conductive layers 21 are buried. Over the inter-level insulating film 22 with the plugs 23 buried in, bit lines 24 extended in parallel with the source lines 20 and superposed above the source lines 20 as projected, and interconnection conductive layers 25 connected to the plugs 23 are formed. The bit lines 24 are formed of an interconnection layer whose level is different from the level of the source lines 20. Over the bit lines 24, a bottom pin type MTJ element 30 is formed.

Over the inter-level insulating film 22 with the bit lines 24, interconnection conductive layers 25 and MTJ elements 30 formed on, an inter-level insulating film is formed. In the inter-level insulating film 26, plugs 27 connected to the interconnection conductive layers 25, and plugs 28 connected to the MTJ elements 30 are buried. Over the inter-level insulating film 26, local interconnections 29 electrically connecting the plugs 27 and the plugs 28 are formed. Thus, the free layer sides of the MTJ elements 30 are electrically connected to the n-drain regions 16 via the plugs 28, the local interconnections 29, the plugs 27, the interconnection conductive layers 25, the plugs 23, the interconnection conductive layers 21 and the plugs 19.

To interconnect the free layer sides of the MTJ elements 30 and the n-type drain regions 16 of the memory cell select transistors, preferably, the bit lines go around the positions, where the n-type drain regions 16 of the memory cell select transistors and the local interconnections 29 are connected, by the plugs 19, 23, 27, etc., and laid out in parallel with the source lines 20. Furthermore, for the minimum dimensions of the layout, preferably, the bit lines 24 are arranged right above the source lines 20.

The source lines 20 and the bit lines 24 laid out in parallel with each other and superposed each other as projected. The word lines 14 are laid out normally to the source lines 20 and the bit lines 24. One transistor and one MTJ element 30 form a memory cell.

The MTJ elements 30 are not specifically limited as long as the MTJ elements 30 have bottom pin type MTJ elements, but the MTJ elements of, e.g., the structure illustrated in FIG. 3 can be used. The MTJ element 30 illustrated in FIG. 3 is formed of a PtMn antiferromagnetic layer 36 of, e.g., a 15 nm-thickness, a coupled pinned layer 37 of the structure of a CoFeB layer (of, e.g., a 2.3 nm-thickness)/a Ru layer 39 (of, e.g., a 0.68 nm-thickness)/a CoFeB layer 40 (of, e.g., a 2.2 nm-thickness), an MgO tunnel insulating film 41 of, e.g. a 1.16 nm-thickness, and a CoFeB free layer 42 of, e.g., a 2 nm-thickness stacked sequentially over a lower electrode 31. The lower electrode 31 is not specifically limited but can be formed of, e.g., the layer structure of a Ta film 32/a Ru film 33/a NiFe film 34/a Ta film 35. The explanation of the upper electrode is omitted. The MTJ element 30 has, e.g., a 0.1 μm-width and a 0.15 μm-length.

FIG. 4 is the equivalent circuit of a memory cell of the spin torque transfer MRAM according to the present embodiment. The memory cell of the spin torque transfer MRAM according to the present embodiment is a 1T-1MTJ memory cell including one memory cell select transistor 1 and one MTJ element 2. The memory cell select transistor 1 has the gate electrode connected to the word line WL and the source terminal connected to the source line SL and the drain terminal connected to the side of the free layer 3 of the MTJ element 2. The side of the pinned layer of the MTJ element 2 is connected to the bit line BL.

As described above, the spin torque transfer MRAM according to the present embodiment is the bottom pin type MTJ element 10, which is advantageous in terms of the processing, as is the spin torque transfer MRAM according to the reference embodiment, but uses the local interconnection 29 for connecting the side of the pinned layer to the bit line 24.

Next, the method of manufacturing the spin torque transfer MRAM according to the present embodiment will be explained with reference to FIGS. 2A-2C.

First, the device isolation region 12 is formed in the p-type silicon substrate 11, and the gate electrodes to be the word lines 14 are formed over the surfaces of the device forming regions surrounded by the device isolation region 12, with the gate insulating film 13 interposed therebetween.

Then, the n-type source regions 15 and the n-type drain regions 16 are formed on both sides of each gate electrode. In this case as well, the source region and the drain region are relatively called, but for the convenience, the side connected to the bit line is the drain region here.

Next, the inter-level insulating film 17 is formed, and then the plugs 18 connected to the n-type source regions 15 and the plugs 19 connected to the n-type drain regions are formed. The source lines 20 are formed, connected to the plugs 18, and the interconnection conductive layers 21 are formed, connected to the plugs 19.

Then, the inter-level insulating film 22 is formed, and then the plugs 23 connected to the interconnection conductive layers 21 are formed.

Next, the bit lines 24 are formed, superposing the source lines 20 as projected, and the interconnection conductive layers 25 are formed, connected to the plugs 23.

Then, the bottom pin type MTJ elements 30 are formed, superposing the bit line 24 as projected. Next, the inter-level insulating film 26 is formed, and then the plugs 27 connected to the interconnection conductive layers 25 are formed. Next, the plugs 28 connected to the MTJ elements 30 are formed.

Next, the plugs 28 and the plugs 27 are interconnected by the local interconnections 29, and the basic structure of the spin torque transfer MRAM according to the present embodiment is completed.

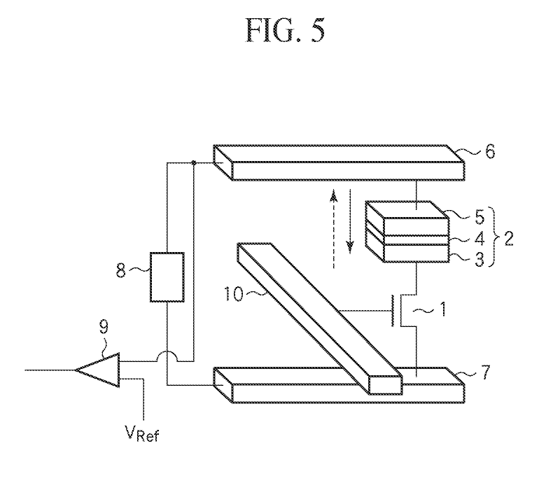

Next, the operation of the spin torque transfer MRAM according to the present embodiment will be explained with reference to FIGS. 5 to 7.

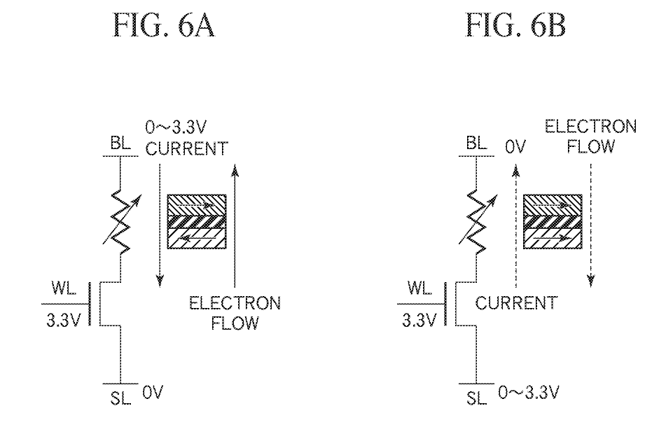

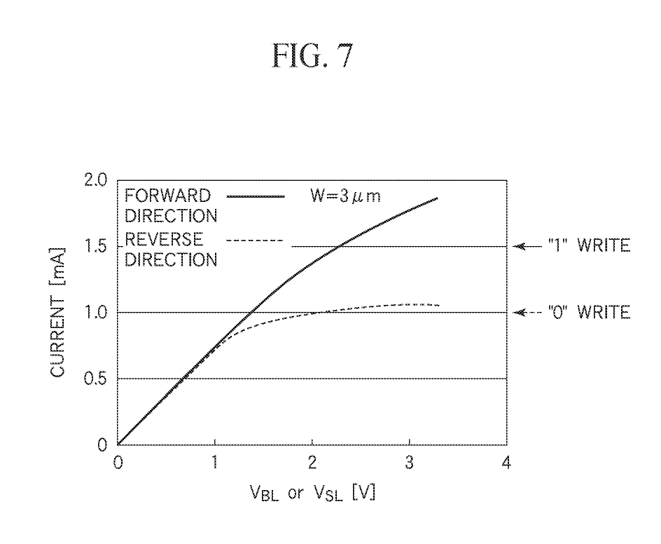

FIG. 5 is a conceptual perspective view of the memory cell forming the spin torque transfer MRAM according to the present embodiment. FIGS. 6A and 6B are views explaining the write operation of the spin torque transfer MRAM according to the present embodiment. FIG. 7 is a graph explaining the current driving power and the write current of the memory cell select transistor.

The memory cell includes a memory cell select transistor 1 and a MTJ element 2. In this case, the MTJ element 2 includes at least a free layer 3, a pinned layer 5, and a tunnel insulating film 4 sandwiched therebetween and has the side of the pinned layer 5 connected to the bit line and the side of the free layer 3 connected to the source line 7.

To the bit line 6 and the source line 7, a write circuit and a read circuit are connected. As exemplified in FIG. 5, a bidirectional write/read voltage generator 8 is connected between the source line 7 and the bit line 6. The bit line 6 is connected also to a sense amplifier 9, and the read output from the bit line 6 is outputted to the sense amplifier 9. Thus, the information memorized in the MTJ element 2 can be read. Reference number 10 in the drawing indicates a word line.

FIGS. 6A and 6B are views explaining the write operation. As illustrated in FIG. 6A, in the 1T-1MTJ memory cell, the antiparallel write (“1” write) whose write current of the MTJ element characteristics is large, is made in the forward direction of the current flow from the side of the bit line, where the current driving power is large. On the other hand, as illustrated in FIG. 6B, the “0” write, whose write current can be smaller, is made in the reverse direction, in which the driving power is low.

FIG. 7 is a view explaining the current driving power and the write current of the memory cell select transistor. As one example, the write current of the memory cell select transistor of a 3 μm-gate width W is shown here.

As shown in FIG. 7, the reverse current driving power of the memory cell select transistor of a 3 μm-gate width is about 1 mA for applied voltage of 3.3 V, and with this reverse current, “0”, whose write current is small, can be written.

On the other hand, “1”, whose write current is large, is written with the forward current, whose current driving power is large, and can be written without any problem. As described above, the present embodiment is efficient in terms of the current driving power, which allows a memory cell select transistor of a smaller size to be used.

As described above, in the present embodiment, the bottom pin type MTJ element, which is advantageous in terms of the processing as is the reference embodiment, is used, and by the use of the local interconnection, the side of the pinned layer is connected to the bit line 24. Accordingly, in the antiparallel write (“1” write), whose write current is large, the current is flowed from the side of the bit line, whose current driving power is large, which makes it possible to write by the use of even a memory cell select transistor whose cell size is small.

### A Second Embodiment

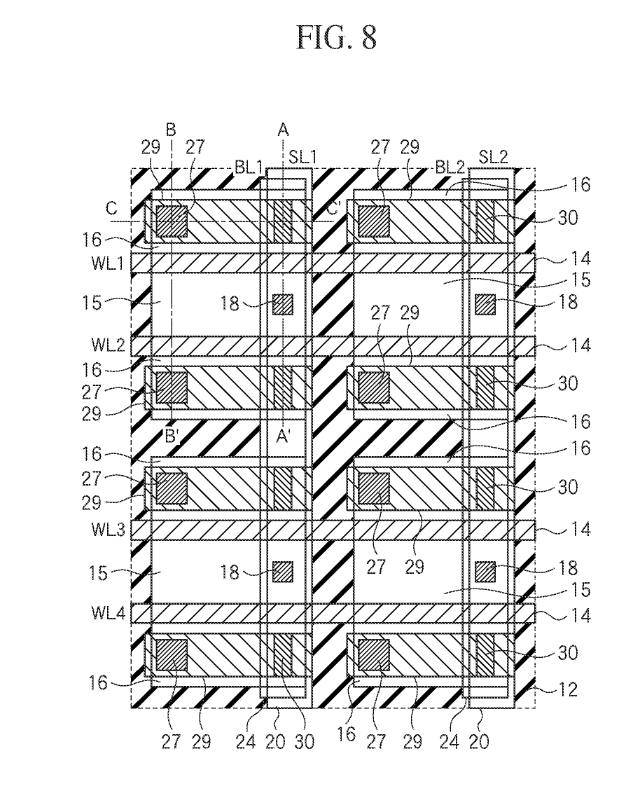

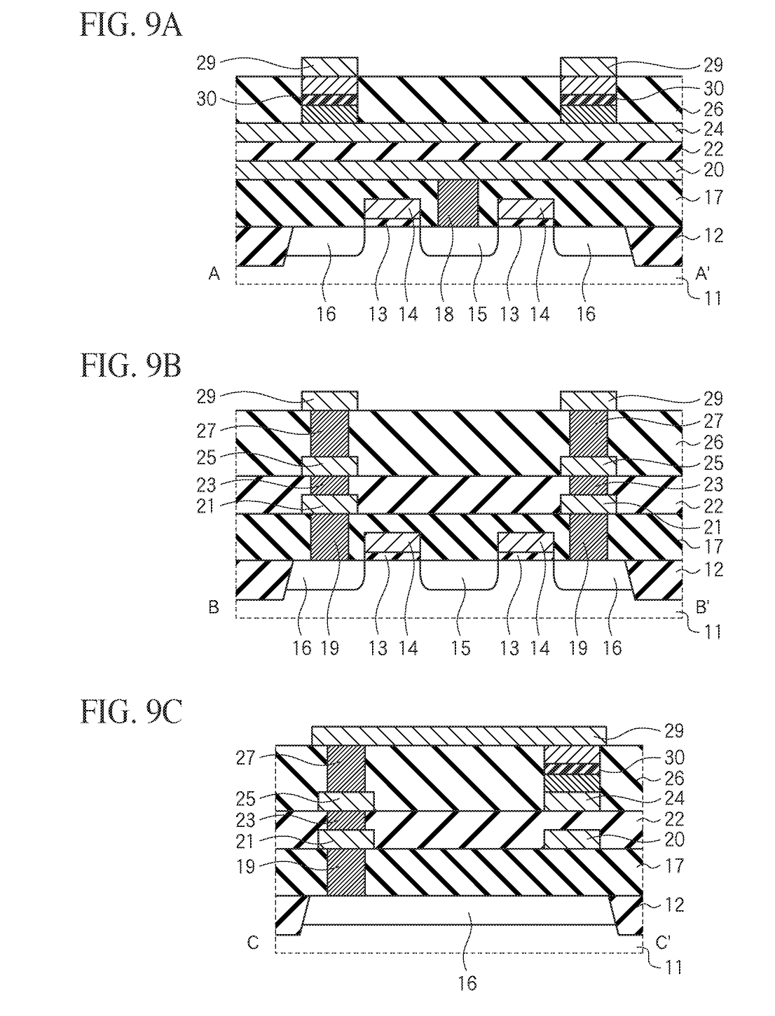

The spin torque transfer MRAM according to a second embodiment will be explained with reference to FIGS. 8 to 9C. The same members of the present embodiment as those of the spin torque transfer MRAM according to the first embodiment illustrated in FIGS. 1 to 7 are represented by the same reference numbers not to repeat or to simplify their explanation.

FIG. 8 is a diagrammatic plan view of the spin torque transfer MRAM according to the present embodiment. FIGS. 9A-9C are diagrammatic sectional views of respective parts of the spin torque transfer MRAM according to the present embodiment.

The spin torque transfer MRAM according to the present embodiment is the same as the spin torque transfer MRAM according to the first embodiment except the connection between the MTJ element 30 and the local interconnection 29.

That is, in the spin torque transfer MRAM according to the present embodiment, as illustrated in FIGS. 9A to 9C, the surface of the inter-level insulating film 26 is planarized, and the surface of the inter-level insulating film 26 and the surfaces of the MTJ elements 30 are even with each other. The local interconnections are formed on the planarized inter-level insulating film 30 and are connected to the MTJ elements 30 at the parts where the MTJ elements 30 are exposed. The processing of connecting the MTJ elements 30 and the local interconnections 29 can be made by the borderless contact process using CMP (chemical mechanical polishing) and etching back.

The use of the borderless contact process makes it unnecessary to open the contact holes over the MTJ elements 30, and the MTJ elements 30 which are downsized can be connected to the local interconnections 29.

It is preferable that the MTJ elements 30 are rectangular. It is also preferable that the ratio of the length of the MTJ elements 30 to the width thereof (aspect ratio) is about 2-3. The MTJ elements 30 may be a rectangle which is lengthy in the direction of extension of the bit lines 24 or the word lines 14. However, in view of facilitating the manufacture, preferably, the MTJ elements 30, which are formed on the bit lines, is a rectangle which is lengthy in the direction of extension of the bit lines 24.

As described above, in the present embodiment, the connection between the MTJ elements and the local interconnections are formed by the borderless contact, which allows the MTJ elements which are downsized to be connected to the local interconnections.

### A Third Embodiment

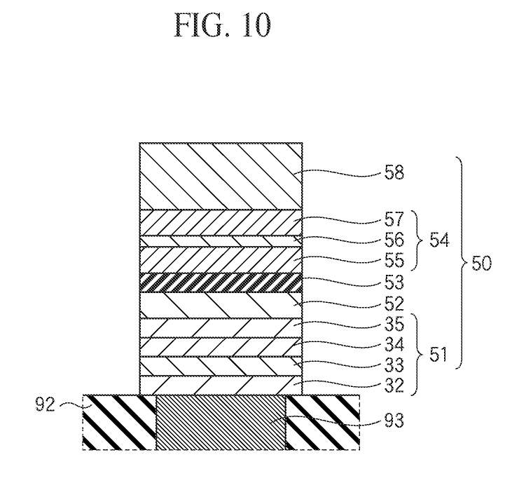

The spin torque transfer MRAM according to a third embodiment will be explained with reference to FIG. 10. The same members of the present embodiment as those of the spin torque transfer MRAM according to the first and the second embodiments illustrated in FIGS. 1 to 9C and the spin torque transfer MRAM according to the reference embodiment illustrated in FIGS. 12 to 19 are represented by the same reference numbers not to repeat or to simplify their explanation.

The spin torque transfer MRAM according to the third embodiment has the same basic memory cell layout as that of the spin torque transfer MRAM according to the reference embodiment illustrated in FIGS. 12 to 19, and only the structure of the MTJ elements will be explained.

FIG. 10 is a diagrammatic sectional view of the MTJ element forming the spin torque transfer MRAM according to the present embodiment. The MTJ element 50 is not specifically limited as long as the MTJ element 50 is a top pin type MTJ element. For example, the MTJ element 50 is formed of a CoFeB free layer 52 of, e.g., a 2 nm-thickness, an MgO tunnel insulating film 53 of, e.g., a 1.16 nm-thickness, a coupled pinned layer 54 of a CoFeB layer 55 (of, e.g., a 2.2 nm-thickness)/a Ru layer 56 (of, e.g., a 0.68 nm-thickness)/a CoFe layer 57 (of, e.g., a 2.3 nm-thickness), and an antiferromagnetic layer 58 sequentially stacked over a lower electrode 51 connected to a plug 93 of W. The lower electrode can have the same structure as that of the first embodiment described above.

In this case, to make the antiferromagnetic layer 58 formed over the coupled pinned layer 54 oriented (111) or (110) for good crystallinity, it is preferable to form the side contacting the antiferromagnetic layer of the CoFe layer 57, which is rich in Co. Specifically, CoFe whose Co composition ratio is 75%-90% can be used.

The antiferromagnetic layer 58 may be formed of PtMn or IrMn. However, when IrMn is used, because of the degradation of the crystallinity due to the location on the upper layer and the film thickness reduction after the etching, the antiferromagnetic layer 58 is preferably formed as thick as 25-30 nm.

As described above, in the present embodiment, the top pin type MTJ element, which is disadvantageous in the processing and the pin characteristics, is used. However, the local interconnection is unnecessary, which makes it possible to decrease the number of the steps of forming the multi-level interconnection structure.

### A Fourth Embodiment

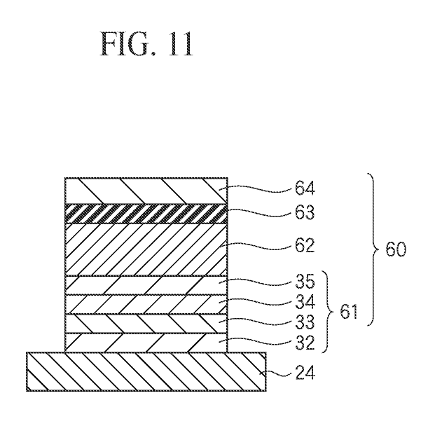

The spin torque transfer MRAM according to a fourth embodiment will be explained with reference to FIG. 11. The same members of the present embodiment as those of the spin torque transfer MRAM according to the first to the third embodiments illustrated in FIGS. 1 to 10 are represented by the same reference numbers not to repeat or to simplify their explanation.

The basic memory cell layout of the spin torque transfer MRAM according to the present embodiment is the same as that of the spin torque transfer MRAM according to the first and the second embodiments illustrated in FIGS. 1 and 8, and only the structure of the MTJ element will be explained.

The spin torque transfer MRAM uses as the MTJ element an MTJ element of the pseudo spin-valve structure, which uses no antiferromagnetic layer, in place of the MTJ element of the exchange-biased spin-valve structure, which has the pinned layer pinned by the antiferromagnetic layer.

FIG. 11 is a diagrammatic sectional view of the MTJ element forming the spin torque transfer MRAM according to the present embodiment. The MTJ element 60 is not specifically limited as long as the MTJ element 60 is an MTJ element of the pseudo spin-valve structure. As illustrated, for example, the MTJ element 60 is formed of a CoFeB pinned layer 62 of, e.g., a 3.0 nm-thickness, an MgO tunnel insulating film 63 of, e.g., a 1.16 nm-thickness, and a CoFeB free layer 64 of, e.g., a 2 nm-thickness sequentially stacked over a lower electrode 61. The lower electrode can have the same structure as that of the first embodiment described above.

In this case, because of the larger film thickness of the CoFeB pinned layer 62 than that of the CoFeB free layer 64, the coercive force becomes relatively stronger, whereby the magnetization direction of the CoFeB pinned layer 62 can be kept constant.

In the present embodiment, the pinned layer which is the filter layer is remote from the memory cell select transistor, and when the antiparallel write (“1” write), whose write current is large, is made, the current is flowed from the side of the bit line whose current driving power is large.

### Modified Embodiments

Embodiments have been explained above, but the conditions and constitutions of the respective embodiments are not essential. For example, in the first and the third embodiments described above, the pinned layer is formed of the coupled pinned layer but may be formed of a single pinned layer.

In the respective embodiments described above, the free layer is formed of CoFeB, but CoFeB is not essential. CoFe may be used, and the CoFe/NiFe layer structure may be used.

In the respective embodiments described above, the tunnel insulating film is formed of MgO, but MgO is not essential. The insulating film of Al₂O₃, Al—O or others may be used.

In the respective embodiments described above, the bit lines and the source lines are arranged in parallel with each other. However, they may not be essentially parallel with each other and may be perpendicular to each other.

In the fourth embodiment described above, the spin torque transfer MRAM includes the MTJ element of the bottom pin type pseudo spin-valve structure, but the spin torque transfer MRAM according to the third embodiment may includes the MTJ element of the top pin type pseudo spin-valve structure.

In the respective embodiments described above, the spin torque transfer MRAM including 1T-1MTJ memory cells have been explained. However, the structure of the memory cells is not limited to this. For example, the spin torque transfer MRAM may include 1T-2MTJ memory cells or 2T-2MTJ memory cells.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A magnetic random access memory comprising:
a magnetic tunnel junction element including a pinned layer, a free layer, and a tunnel insulating film formed between the pinned layer and the free layer; and
a memory cell select transistor having one diffused region electrically connected to a side of the free layer of the magnetic tunnel junction element.

2. The magnetic random access memory according to claim 1, further comprising:
a write circuit connected between a side of the pinned layer of the magnetic tunnel junction element and the other diffused region of the memory cell select transistor, the write circuit, upon writing a high resistance state in the magnetic tunnel junction element, flowing a write current from the pinned layer to the free layer and, upon writing a low resistance state in the magnetic tunnel junction element, flowing a write current from the free layer to the pinned layer.

3. The magnetic random access memory according to claim 1, wherein
the magnetic tunnel junction element is a magnetic tunnel junction element formed of the pinned layer, the tunnel insulating film and the free layer stacked sequentially from the side of a lower electrode.

4. The magnetic random access memory according to claim 3, wherein
the free layer of the magnetic tunnel junction element is electrically connected to said one diffused region of the memory cell select transistor via a first interconnection.

5. The magnetic random access memory according to claim 3, wherein
the magnetic tunnel junction element further including an antiferromagnetic layer formed in contact with the pinned layer.

6. The magnetic random access memory according to claim 1, wherein
the magnetic tunnel junction element is a magnetic tunnel junction element formed of the free layer, the tunnel insulating film and the pinned layer stacked sequentially from the side of a lower electrode.

7. The magnetic random access memory according to claim 6, wherein
the magnetic tunnel junction element is laid out, superposing, as projected, a plug connecting the lower electrode and said one diffused region of the memory cell select transistor.

8. The magnetic random access memory according to claim 6, wherein
the magnetic tunnel junction element further including an antiferromagnetic layer formed in contact with the pinned layer.

9. The magnetic random access memory according to claim 8, wherein
the magnetic tunnel junction element has at least a part of the pinned layer, which is in contact with the antiferromagnetic layer, formed of CoFe of a 75%-90% Co composition ratio.

10. The magnetic random access memory according to claim 8, wherein
the antiferromagnetic layer is formed of IrMn, and the IrM has a film thickness of 25-30 nm.

11. The magnetic random access memory according to claim 1, wherein
the magnetic tunnel junction element is a magnetic tunnel junction element of a pseudo spin-valve structure, which retains a magnetization direction of the pinned layer by a difference of the pinned layer and the free layer in a coercive force.

12. The magnetic random access memory according to claim 1, wherein
a gate width of the memory cell select transistor is not more than 3 μm.

13. A magnetic random access memory comprising:
a magnetic tunnel junction element including a pinned layer, a free layer, and a tunnel insulating film formed between the pinned layer and the free layer;
a memory cell select transistor having one diffused region electrically connected to a side of the free layer of the magnetic tunnel junction element;
a bit line electrically connected to a side of the pinned layer of the magnetic tunnel junction element;
a source line extended in parallel with the bit line and electrically connected to the other diffused region of the memory cell select transistor; and
a word line extended, intersecting the bit line and electrically connected to a gate electrode of the memory cell select transistor.

14. The random access memory according to claim 13, wherein
said one diffused region of the memory cell select transistor is electrically connected to a side of the free layer of the magnetic tunnel junction element via a first interconnection.

15. The magnetic random access memory according to claim 14, wherein
the first interconnection is electrically connected to said one diffused region of the memory cell select transistor at a position different from a position where the magnetic tunnel junction element is formed.

16. The magnetic random access memory according to claim 13, wherein
the magnetic tunnel junction element is laid out, superposing above the bit line, as projected.

17. The magnetic random access memory according to claim 13, wherein
the bit line and the source line are formed of interconnection layers of different levels from each other.

18. The magnetic random access memory according to claim 13, wherein
the bit line and the source line are laid out, superposing each other as projected.

19. The magnetic random access memory according to claim 13, further comprising:
a write circuit connected between the bit line and the source line, the write circuit, upon writing a high resistance state in the magnetic tunnel junction element, flowing a write current from the pinned layer to the free layer and, upon writing a low resistance state in the magnetic tunnel junction element, flowing a write current from the free layer to the pinned layer.
